(19) United States
(12) Patent Application Publication
(10) Pub. No.: US 2026/0096456 A1
(43) Pub. Date: Apr. 2, 2026

(54) SEMICONDUCTOR PACKAGE

(71) Applicant: SAMSUNG ELECTRONICS CO.,LTD., Suwon-si (KR)

(72) Inventor: Hyeonjeong HWANG, Suwon-si (KR)

(73) Assignee: SAMSUNG ELECTRONICS CO.,LTD., Suwon-si (KR)

(21) Appl. No.: 19/169,706

(22) Filed: Apr. 3, 2025

(30) Foreign Application Priority Data
Oct. 2, 2024 (KR) 10-2024-0134211

(51) Int. Cl. H01L 23/538; H01L 21/48; H01L 23/00; H01L 25/18; H05K 1/18; H10B 80/00; H10D 80/30

(52) U.S. Cl. CPC H10W 70/65; H10W 70/095; H10W 70/611; H10W 90/00; H10W 90/401; H05K 1/181; H10B 80/00; H10D 80/30; H10W 74/15; H10W 80/312; H10W 80/327; H10W 90/20; H10W 90/297; H10W 90/722; H10W 90/724; H10W 90/732; H10W 90/794

(57) ABSTRACT

A semiconductor package may include: a substrate; a unit chip package on the substrate; a base chip horizontally spaced apart from the unit chip package on the substrate; a first vertical connection structure between the substrate and the unit chip package; and a second vertical connection structure between the substrate and the base chip. One of the first vertical connection structure and the second vertical connection structure may include: conductive lines spaced apart in a first direction and a second direction that are parallel to an upper surface of the substrate and intersect, wherein the conductive lines each have a first side surface and a second side surface that faces the first side surface in the first direction; and a seed pattern in contact with the conductive lines. The seed pattern may be in contact with second side surfaces of the conductive lines.

### CROSS-REFERENCE TO RELATED APPLICATION

This U.S. non-provisional patent application claims priority under 35 U.S.C. § 119 to Korean Patent Application No.10-2024-0134211 filed on Oct. 2, 2024, in the Korean Intellectual Property Office, the entire contents of which are hereby incorporated by reference.

### BACKGROUND

### 1. Field

The disclosure relates to a semiconductor package. More specifically, the disclosure relates to a semiconductor package including a chiplet structure in which individual chips are connected by a connection structure.

### 2. Description of Related Art

With the advance in electronic industry, there is an increasing demand for high-performance, high-speed and compact electronic components. To meet such a demand, packaging technologies are being recently developed to mount a plurality of semiconductor chips in a single package.

A semiconductor package is provided to implement an integrated circuit chip for use in electronic products. Typically, a semiconductor package is configured such that a semiconductor chip is mounted on a printed circuit board (PCB) and bonding wires or bumps are used to electrically connect the semiconductor chip to the printed circuit board. The semiconductor packages have been variously developed for purposes of small size, light weight, and low fabrication cost with the development of an electronic industry. In addition, many kinds of semiconductor packages have seen the expansion of their application field such as high-capacity mass storage devices.

### SUMMARY

One or more embodiments provide a semiconductor package with improved electrical characteristics and reliability.

The problem to be solved by the disclosure is not limited to the problems mentioned above, and other problems not mentioned may be clearly understood by those skilled in the art from the description below.

According to one or more example embodiments, a semiconductor package may include: a substrate; a unit chip package on the substrate; a base chip horizontally spaced apart from the unit chip package on the substrate; a first vertical connection structure between the substrate and the unit chip package; and a second vertical connection structure between the substrate and the base chip. One of the first vertical connection structure and the second vertical connection structure may include: conductive lines spaced apart in a first direction and a second direction that are parallel to an upper surface of the substrate and intersect, wherein the conductive lines each have a first side surface and a second side surface that faces the first side surface in the first direction; and a seed pattern in contact with the conductive lines. The seed pattern may be in contact with second side surfaces of the conductive lines.

According to one or more example embodiments, a semiconductor package may include: a substrate; a unit chip package on the substrate; a base chip horizontally spaced apart from the unit chip package on the substrate; a first vertical connection structure between the substrate and the unit chip package; and a second vertical connection structure between the substrate and the base chip. One of the first vertical connection structure and the second vertical connection structure may include conductive lines, and the conductive lines may have a rectangular shape when viewed in a plan view and have a rectangular pillar shape extending in a vertical direction perpendicular to an upper surface of the substrate.

According to one or more example embodiments, a semiconductor package may include: a package substrate; a substrate on the package substrate; a unit chip package on the substrate; a base chip on the substrate and spaced apart from the unit chip package in a first direction parallel to an upper surface of the package substrate; a horizontal connection structure between the unit chip package and the substrate and extending from the base chip to the substrate; a first vertical connection structure between the substrate and the unit chip package; and a second vertical connection structure between the substrate and the base chip. The horizontal connection structure may connect the unit chip package and the base chip through lower connection terminals of the unit chip package and base connection terminals of the base chip. One of the first vertical connection structure and the second vertical connection structure may include: conductive lines spaced apart in the first direction and a second direction parallel to the upper surface of the package substrate and intersecting the first direction; and a seed pattern in contact with the conductive lines. The conductive lines may each have a first side surface and a second side surface facing the first side surface in the first direction, and the seed pattern may be in contact with second side surfaces of the conductive lines.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a plan view of a semiconductor package according to one or more embodiments;

FIG. 2 is a cross-sectional view taken along line A-A′ of FIG. 1 according to one or more embodiments;

FIG. 3A is an enlarged plan view of a vertical connection structure of FIG. 2 according to one or more embodiments;

FIG. 3B is a cross-sectional view taken along line A-A′ of FIG. 3A according to one or more embodiments;

FIG. 4 is a cross-sectional view illustrating a method of manufacturing a semiconductor package according to one or more embodiments;

FIG. 5 is a cross-sectional view illustrating a method of manufacturing a semiconductor package according to one or more embodiments;

FIG. 6 is a cross-sectional view illustrating a method of manufacturing a semiconductor package according to one or more embodiments;

FIG. 7 is a cross-sectional view illustrating a method of manufacturing a semiconductor package according to one or more embodiments;

FIG. 8 is a view illustrating a method of manufacturing a vertical connection structure according to one or more embodiments;

FIG. 9A is a view illustrating a method of manufacturing a vertical connection structure according to one or more embodiments;

FIG. 9B is a view illustrating a method of manufacturing a vertical connection structure according to one or more embodiments;

FIG. 10A is a view illustrating a method of manufacturing a vertical connection structure according to one or more embodiments;

FIG. 10B is a view illustrating a method of manufacturing a vertical connection structure according to one or more embodiments;

FIG. 11 is a view illustrating a method of manufacturing a vertical connection structure according to one or more embodiments;

FIG. 12A is a view illustrating a method of manufacturing a vertical connection structure according to one or more embodiments;

FIG. 12B is a view illustrating a method of manufacturing a vertical connection structure according to one or more embodiments;

FIG. 13A is a view illustrating a method of manufacturing a vertical connection structure according to one or more embodiments;

FIG. 13B is a view illustrating a method of manufacturing a vertical connection structure according to one or more embodiments;

FIG. 14A is a view illustrating a method of manufacturing a vertical connection structure according to one or more embodiments;

FIG. 14B is a view illustrating a method of manufacturing a vertical connection structure according to one or more embodiments;

FIG. 15 is a cross-sectional view illustrating a method of manufacturing a semiconductor package according to one or more embodiments;

FIG. 16 is a cross-sectional view illustrating a method of manufacturing a semiconductor package according to one or more embodiments; and

FIG. 17 is a cross-sectional view illustrating a semiconductor package according to one or more embodiments, and is a cross-sectional view taken along line A-A′ of FIG. 1.

### DETAILED DESCRIPTION

Hereinafter, the disclosure will be described in detail by describing embodiments of the disclosure with reference to the attached drawings.

In the disclosure, spatially relative terms such as “top”, “bottom”, “upper”, “lower”, “side”, “up”, “down”, “horizontal,” “vertical,” “higher,” “lower,” etc. are used to easily explain the positional relationship of each component when viewed from a direction depicted in the drawings. Therefore, spatially relative terms indicating the positional relationship of each component may be understood differently when viewed from a direction other than the direction depicted in the drawings.

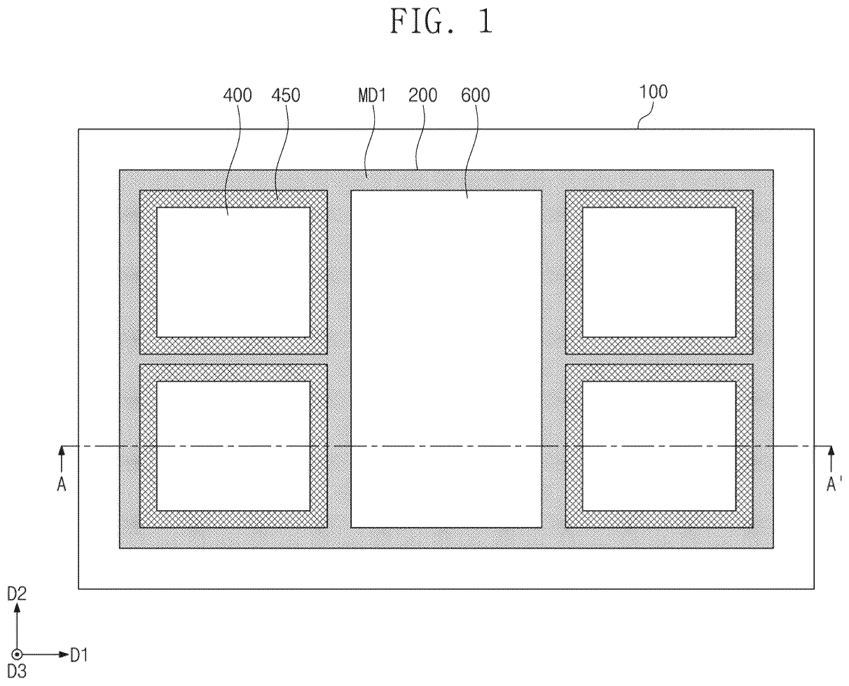

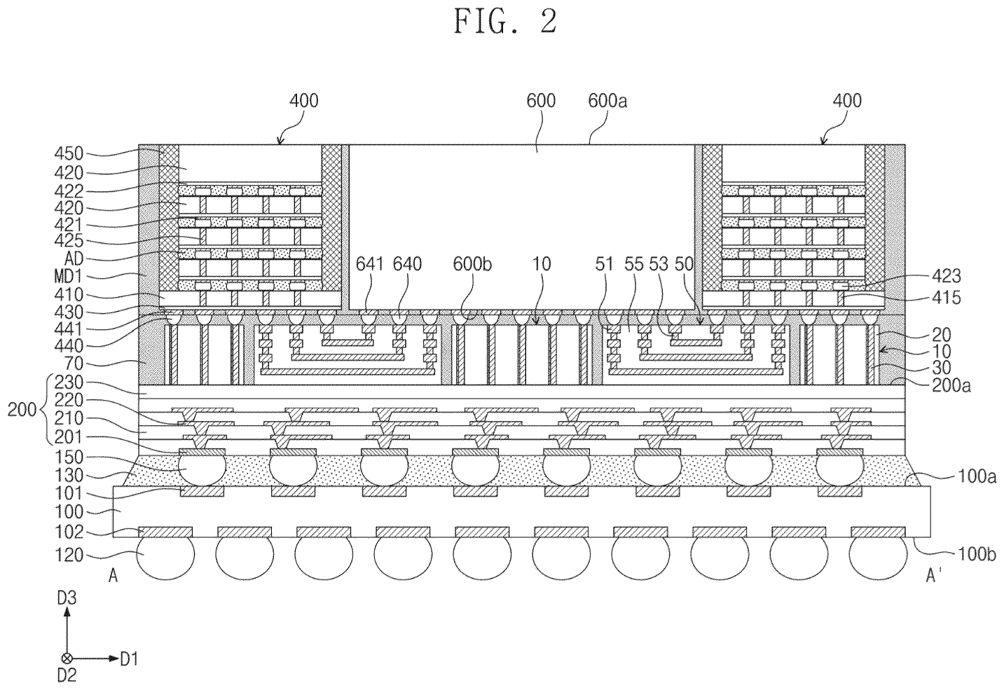

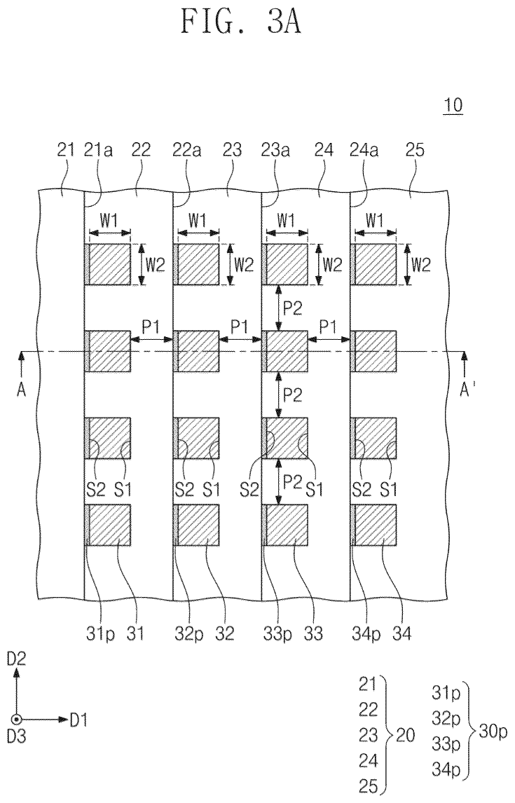

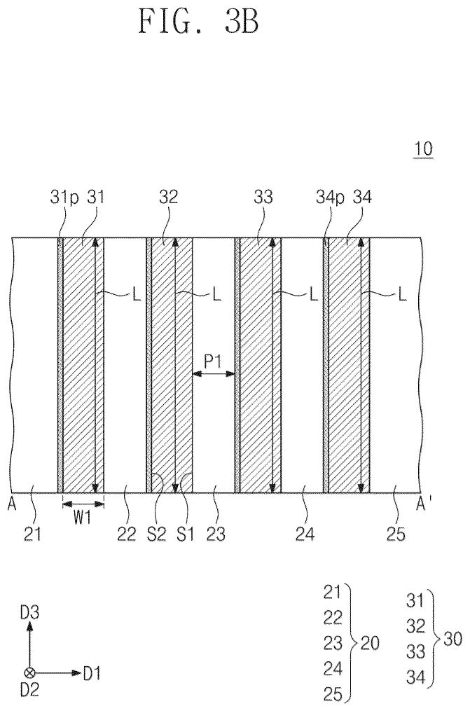

FIG. 1 is a plan view of a semiconductor package according to some embodiments of the disclosure. FIG. 2 is a cross-sectional view taken along line A-A′ of FIG. 1. FIG. 3A is an enlarged plan view of a vertical connection structure of FIG. 2. FIG. 3B is a cross-sectional view taken along line A-A′ of FIG. 3A.

Referring to FIGS. 1 to 3B, a semiconductor package according to one or more embodiments of the disclosure may include a package substrate 100, a redistribution substrate 200, a unit chip package 400, and a base chip 600. The package substrate 100 may be, for example, a printed circuit board (PCB). The package substrate 100 may have an upper surface 100a and a lower surface 100b facing each other in a third direction D3. In this specification, a first direction D1 and a second direction D2 may be directions that are parallel to the upper surface 100a of the package substrate 100 and intersect each other. The third direction D3 may be a vertical direction D3 that is perpendicular to the upper surface 100a of the package substrate 100. The third direction D3 may also be referred to as a vertical direction D3. For example, the first to third directions D1, D2, and D3 may be directions that are orthogonal to each other.

The unit chip package 400 and the base chip 600 may have a chiplet structure. A chiplet may mean dividing an existing chip by function, forming individual chips, and then connecting the chips with a connection structure.

Lower chip pads 102 may be disposed on the lower surface 100b of the package substrate 100. The lower chip pads 102 may be electrically connected to a circuit layer in the package substrate 100. External connection terminals 120 may be respectively disposed on the lower chip pads 102 and may be respectively connected to the lower chip pads 102. The external connection terminals 120 may be electrically connected to the package substrate 100 through the lower chip pads 102. The external connection terminals 120 may include solder balls or solder bumps. The external connection terminals 120 may be an alloy including at least one of tin (Sn), silver (Ag), copper (Cu), nickel (Ni), bismuth (Bi), indium (In), antimony (Sb), or cerium (Ce).

Upper chip pads 101 may be disposed on the upper portion of the package substrate 100. The upper surfaces of the upper chip pads 101 may be exposed without being covered by the package substrate 100. The upper chip pads 101 may be electrically connected to a circuit layer in the package substrate 100.

The upper chip pads 101 and the lower chip pads 102 may include metal (e.g., copper).

The redistribution substrate 200 may be disposed on the package substrate 100. The redistribution substrate 200 may include a plurality of wiring insulating layers 210, under bump pads 201, wiring patterns 220, and a redistribution circuit layer 230 that are stacked in the vertical direction D3. The redistribution circuit layer 230 may include integrated circuits.

The wiring insulating layers 210 may include an organic material, such as a photo-imageable dielectric (PID), for example. The photo-imageable dielectric may be a polymer. The photo-imageable dielectric may include, for example, at least one of a photosensitive polyimide, a polybenzoxazole, a phenol-based polymer, and a benzocyclobutene-based polymer. In FIG. 2, an interface between the wiring insulating layers 210 is visually distinguished, but the disclosure is not limited thereto. According to one or more other embodiments, the interface between adjacent wiring insulating layers 210 may not be visually distinguished.

The under bump pad 201 may be disposed on a lower surface of the redistribution substrate 200. A plurality of under bump pads 201 may be provided. The under bump pads 201 may be spaced apart from each other in the first direction D1 and/or the second direction D2. The under bump pads 201 may be disposed on a lower surface of the lowermost wiring insulating layer 210 among the wiring insulating layers 210. The under bump pads 201 may include a metal (e.g., copper).

The wiring patterns 220 may be disposed in the wiring insulating layers 210. Each of the wiring patterns 220 may include a via portion and a wiring portion integrally connected to each other. The wiring portion may be a pattern for horizontal connection in the redistribution substrate 200. The via portion may be a portion that vertically connects the wiring patterns 220 in the wiring insulating layers 210. The wiring portion may be provided on the via portion. The via portion and the wiring portion may be connected to each other without an interface. The lowermost wiring patterns 220 among the wiring patterns 220 may be connected to the under bump pads 201, respectively. The wiring patterns 220 may include a metal (e.g., copper).

Redistribution connection terminals 150 may be disposed between the package substrate 100 and the redistribution substrate 200. The redistribution connection terminals 150 may be respectively disposed on the under bump pads 201 and may be respectively connected to the upper chip pads 101. The redistribution connection terminals 150 may be an alloy including at least one of tin (Sn), silver (Ag), copper (Cu), nickel (Ni), bismuth (Bi), indium (In), antimony (Sb), or cerium (Ce). The redistribution substrate 200 and the package substrate 100 may be electrically connected to each other through the redistribution connection terminals 150.

An underfill pattern 130 may be interposed between the redistribution substrate 200 and the package substrate 100. The underfill pattern 130 may cover a side surface of each of the redistribution connection terminals 150. The underfill pattern 130 may include an insulating polymer material such as an epoxy resin.

The unit chip package 400 and the base chip 600 may be disposed to be spaced apart from each other in the first direction D1 on the redistribution substrate 200. A plurality of unit chip packages 400 may be provided. The unit chip packages 400 may be disposed to be spaced apart from each other in the first direction D1 with the base chip 600 interposed therebetween. The unit chip packages 400 may be disposed to be spaced apart from each other in the second direction D2. The number and arrangement of the unit chip packages 400 and the base chip 600 may be variously changed depending on the design.

The unit chip package 400 may be a high bandwidth memory (HBM). The unit chip package 400 may include a lower semiconductor chip 410 and a plurality of semiconductor chips 420 stacked on the lower semiconductor chip 410. The plurality of semiconductor chips 420 may be disposed on an upper surface of the lower semiconductor chip 410 and may be stacked in the vertical direction D3. In FIG. 2, a structure in which four semiconductor chips 420 are stacked on the lower semiconductor chip 410 is illustrated, but the disclosure is not limited thereto. There may be more than one semiconductor chip stacked on the lower semiconductor chip 410.

The lower semiconductor chip 410 may include a lower circuit layer 430 adjacent to a lower surface of the lower semiconductor substrate. The lower circuit layer 430 may include integrated circuits formed on the lower semiconductor substrate. Lower penetration electrodes 415 that penetrate the lower semiconductor substrate. The lower penetration electrodes 415 may be horizontally spaced apart from each other in the lower semiconductor substrate. The lower penetration electrodes 415 may be electrically connected to the lower circuit layer 430. The lower penetration electrodes 415 may include a metal (e.g., copper, tungsten, titanium, tantalum, etc.).

The plurality of semiconductor chips 420 may be sequentially stacked in a third direction D3 on an upper surface of the lower semiconductor chip 410. Each of the plurality of semiconductor chips 420 may include a semiconductor substrate, a circuit layer 422, chip pads 421, bumps 423, and penetration electrodes 425. The penetration electrodes 425 may penetrate the semiconductor substrate and may be horizontally spaced apart from each other in the semiconductor substrate. The penetration electrodes 425 may be electrically connected to the circuit layer. The uppermost semiconductor chip among the plurality of semiconductor chips 420 may not include penetration electrodes. The penetration electrodes 425 may include a metal (e.g., copper, tungsten, titanium, tantalum, etc.).

Among the plurality of semiconductor chips 420, the semiconductor chips 420 that are adjacent to each other in the vertical direction D3 may be electrically connected through the bumps 423 disposed therebetween. The lowest semiconductor chip 420 among the plurality of semiconductor chips 420 and the lower semiconductor chip 410 may be electrically connected through the bumps 423 disposed therebetween. The bumps 423 may include a conductive material and may have at least one of a solder ball, a bump, and a pillar.

The unit chip package 400 may further include non-conductive layers AD interposed between the lowest semiconductor chip among the plurality of semiconductor chips 420 and the lower semiconductor chip 410, and between the plurality of semiconductor chips 420, respectively. Each of the non-conductive layers AD may fill a space between the bumps 423 disposed between the semiconductor chips 420 that are adjacent to each other in the vertical direction D3. According to some embodiments, each of the non-conductive layers AD may include a protrusion protruding from a side surface of an adjacent semiconductor chip 420. The non-conductive layers AD may include a thermosetting polymer resin, and for example, may include at least one of a bisphenol-type epoxy resin, a novolak-type epoxy resin, a phenol resin, a urea resin, a melamine resin, an unsaturated polyester resin, and a resorcinol resin.

A mold layer 450 may be disposed on the lower semiconductor chip 410. The mold layer 450 may cover side surfaces of the plurality of semiconductor chips 420. The mold layer 450 may cover protrusions, which are side surfaces of the non-conductive layers AD. The mold layer 450 may extend from an upper surface of the lower semiconductor chip 410 to an upper surface of the uppermost semiconductor chip among the plurality of semiconductor chips 420. The mold layer 450 may expose the upper surface of the uppermost semiconductor chip among the plurality of semiconductor chips 420. An upper surface of the mold layer 450 may be coplanar with the upper surface of the uppermost semiconductor chip among the plurality of semiconductor chips 420. The mold layer 450 may include an insulating material (e.g., an epoxy molding compound (EMC)).

The plurality of semiconductor chips 420 may be memory chips. The plurality of semiconductor chips 420 may be identical semiconductor chips, and for example, may be identical memory chips. The lower semiconductor chip 410 may be a memory chip, a logic chip, an application processor (AP) chip, or a system on chip (SOC). The plurality of semiconductor chips 420 and the lower semiconductor chip 410 may be electrically connected to each other and may constitute a high bandwidth memory (HBM) chip.

Lower chip pads 441 and lower connection terminals 440 may be disposed below the lower circuit layer 430 of the lower semiconductor chip 410. The lower connection terminals 440 may be disposed on the lower chip pads 441, respectively. The lower connection terminals 440 may be an alloy including at least one of tin (Sn), silver (Ag), copper (Cu), nickel (Ni), bismuth (Bi), indium (In), antimony (Sb), or cerium (Ce).

The base chip 600 may be, for example, one of a central processing unit (CPU), a graphics processing unit (GPU), and an application specific integrated circuit (ASIC).

The base chip 600 may have an upper surface 600a and a lower surface 600b facing each other in the third direction D3. Base chip pads 641 and base connection terminals 640 may be disposed on the lower surface 600b of the base chip 600. The base connection terminals 640 may be disposed on the base chip pads 641, respectively. The base connection terminals 640 may be an alloy including at least one of tin (Sn), silver (Ag), copper (Cu), nickel (Ni), bismuth (Bi), indium (In), antimony (Sb), or cerium (Ce).

The semiconductor package may include a horizontal connection structure 50 connecting the unit chip package 400 and the base chip 600. The horizontal connection structure 50 may be disposed between the unit chip package 400 and the redistribution substrate 200, and may extend between the base chip 600 and the redistribution substrate 200. A plurality of horizontal connection structures 50 may be provided. Each of the horizontal connection structures 50 may correspondingly connect the unit chip package 400 and the base chip 600.

The horizontal connection structure 50 may include a horizontal connection insulating layer 55, horizontal circuit wiring lines 51, and horizontal contact plugs 53. The horizontal circuit wiring lines 51 and the horizontal contact plugs 53 may be provided in the horizontal connection insulating layer 55. Some of the horizontal circuit wiring lines 51 may be electrically connected to the lower connection terminals 440 of the corresponding unit chip package 400. Others of the horizontal circuit wiring lines 51 may be electrically connected to the corresponding base connection terminals 640. The horizontal contact plugs 53 may electrically connect the horizontal circuit wiring lines 51. Accordingly, the base chip 600 and the unit chip package 400 may be electrically connected through the horizontal circuit wiring lines 51 and the horizontal contact plugs 53 of the horizontal connection structure 50.

The semiconductor package may further include a vertical connection structure 10 between the redistribution substrate 200 and the unit chip package 400. The vertical connection structure 10 may also be interposed between the redistribution substrate 200 and the base chip 600. That is, a plurality of vertical connection structures (e.g. a first vertical connection structure and a second vertical connection structure) 10 may be provided. Each of the vertical connection structures 10 may include conductive lines 30 and a vertical connection insulating layer 20. The conductive lines 30 may be spaced apart from each other in the first and second directions D1 and D2. The conductive lines 30 may extend in the third direction D3. Each of the conductive lines 30 may be connected to a corresponding lower connection terminal 440 or a corresponding base connection terminal 640. The conductive lines 30 may be electrically connected to the redistribution circuit layer 230 of the redistribution substrate 200. The unit chip package 400 and the base chip 600 may be electrically connected to the redistribution substrate 200 through the vertical connection structure 10. Specifically, the unit chip package 400 may be electrically connected to the redistribution substrate 200 through the first vertical connection structure, and the base chip 600 may be electrically connected to the redistribution substrate 200 through the second vertical connection structure.

Referring to FIGS. 3A and 3B, the vertical connection insulating layer 20 of the vertical connection structure 10 may include a plurality of insulating layers 21, 22, 23, 24, and 25 stacked in the first direction D1. The vertical connection structure 10 may include conductive lines 30 respectively disposed on upper surfaces 21a, 22a, 23a, 24a, and 25a of the plurality of insulating layers 21, 22, 23, 24, and 25. The vertical connection structure 10 may include seed patterns 30p interposed between upper surfaces 21a, 22a, 23a, 24a, and 25a of a plurality of insulating layers 21, 22, 23, 24, and 25 and the conductive lines 30. Each of the conductive lines 30 may have a rectangular column shape. For example, each of the conductive lines 30 may have a rectangular parallelepiped shape. When viewed in a plan view, each of the conductive lines 30 may have a square shape. For example, when viewed in a plan view, each of the conductive lines 30 may have a rectangular shape. Although a structure in which five insulating layers 21, 22, 23, 24, and 25 are stacked is exemplarily illustrated in FIGS. 3A and 3B, the disclosure is not limited thereto. The number of insulating layers and conductive lines may be variously changed depending on a design.

The plurality of insulating layers 21, 22, 23, 24, and 25 may include a first insulating layer 21, a second insulating layer 22, a third insulating layer 23, a fourth insulating layer 24, and a fifth insulating layer 25 that are sequentially stacked in the first direction D1, as illustrated. The conductive lines 30 may include first conductive lines 31, second conductive lines 32, third conductive lines 33, and fourth conductive lines 34. The seed patterns 30p may include first seed patterns 31p, second seed patterns 32p, third seed patterns 33p, and fourth seed patterns 34p.

The first insulating layer 21 may include a first side surface 21a and a second side surface 21b that face each other in the first direction D1. The first conductive line 31 may be disposed on the first side surface 21a of the first insulating layer 21. A plurality of first conductive line 31 may be provided. The first conductive lines 31 may be spaced apart from each other in the second direction D2 on the first side surface 21a of the first insulating layer 21.

The first conductive lines 31 that are adjacent to each other in the second direction D2 may be spaced apart from each other by a second distance P2 in the second direction D2. According to some embodiments, the second distance P2 may be 3 um to 30 um.

Each of the first conductive lines 31 may have a first width W1 in the first direction D1 and a second width W2 in the second direction D2. According to some embodiments, each of the first width W1 and the second width W2 may be 1 um to 10 um.

Each of the first seed patterns 31p may be interposed between the first side surface 21a of the first insulating layer 21 and each of the first conductive lines 31. Each of the first conductive lines 31 may have a first side surface S1 and a second side surface S2 facing each other in the first direction D1. Each of the first seed patterns 31p may be interposed between the first side surface 21a of the first insulating layer 21 and the second side surface S2 of each of the first conductive lines 31. Each of the first seed patterns 31p may be aligned with the corresponding first conductive line 31 in the first direction D1. Each of the first seed patterns 31p may be horizontally overlapped with the corresponding first conductive line 31.

Each of the first conductive lines 31 may have a length L in the third direction D3. According to some embodiments, the length L may be 7 um to 33 um.

The first seed patterns 31p may serve as a seed for forming the first conductive lines 31. The first seed patterns 31p may include a material that acts as an adhesive and a barrier, and a seed material of the first conductive lines 31. For example, the first seed patterns 31p may include at least one of copper, titanium, tungsten, and nickel. Preferably, the first seed patterns 31p may include titanium and copper. The first conductive lines 31 may include a conductive material. For example, the first conductive lines 31 may include copper.

The second insulating layer 22 may be disposed on the first side surface 21a of the first insulating layer 21. The second insulating layer 22 may cover the first conductive lines 31. The second insulating layer 22 may have a first side surface 22a. The first side surface 22a of the second insulating layer 22 may face the first side surface 21a of the first insulating layer 21 in the first direction D1. The second conductive line 32 may be disposed on the first side surface 22a of the second insulating layer 22. A plurality of second conductive lines 32 may be provided. The second conductive lines 32 may be spaced apart from each other in the second direction D2 on the first side surface 21a of the second insulating layer 22.

The second conductive lines 32 adjacent to each other in the second direction D2 may be spaced apart from each other by a second distance P2 in the second direction D2. According to some embodiments, the second distance P2 may be 3 um to 30 um.

The first conductive lines 31 and the second conductive lines 32 may be spaced apart from each other in the first direction D1 with a portion of the second insulating layer 22 interposed therebetween. Among the first and second conductive lines 31 and 32, the first conductive line 31 and the second conductive line 32 adjacent to each other in the first direction D1 may be spaced apart from each other by a first distance P1 in the first direction D1. According to some embodiments, the first distance P1 may be 3 um to 30 um. The first distance P1 may be a distance in the first direction D1 between the first side surface S1 of the first conductive line 31 and the first side surface 22a of the second insulating layer 22.

Each of the second conductive lines 32 may have a first width W1 in the first direction D1 and a second width W2 in the second direction D2. According to some embodiments, each of the first width W1 and the second width W2 may be 1 um to 10 um.

Each of the second seed patterns 32p may be interposed between the first side surface 22a of the second insulating layer 22 and each of the second conductive lines 32. Each of the second conductive lines 32 may have a first side surface S1 and a second side surface S2 facing each other in the first direction D1. Each of the second seed patterns 32p may be interposed between the first side surface 22a of the second insulating layer 22 and the second side surface S2 of each of the second conductive lines 32. Each of the second seed patterns 32p may be aligned with the corresponding second conductive line 32 in the first direction D1. Each of the second seed patterns 32p may be horizontally overlapped with the corresponding second conductive line 32.

Each of the second conductive lines 32 may have a length L in the third direction D3. According to some embodiments, the length L may be 7 um to 33 um.

The second seed patterns 32p and the second conductive lines 32 may include substantially the same material as that of the first seed patterns 31p and the first conductive lines 31, respectively.

A third insulating layer 23 may be disposed on the first side surface 22a of the second insulating layer 22. The third insulating layer 23 may cover the second conductive lines 32. The third insulating layer 23 may have a first side surface 23a. The first side surface 23a of the third insulating layer 23 may face the first side surface 22a of the second insulating layer 22 in the first direction D1. The third conductive line 33 may be disposed on the first side surface 23a of the third insulating layer 23. A plurality of third conductive lines 33 may be provided. The third conductive lines 33 may be spaced apart from each other in the second direction D2 on the first side surface 23a of the third insulating layer 23.

The third conductive lines 33 adjacent to each other in the second direction D2 may be spaced apart from each other by a second distance P2 in the second direction D2. According to some embodiments, the second distance P2 may be 3 um to 30 um.

The second conductive lines 32 and the third conductive lines 33 may be spaced apart from each other in the first direction D1 with a portion of the third insulating layer 23 interposed therebetween. Among the second and third conductive lines 32 and 33, the second conductive line 32 and the third conductive line 33 adjacent to each other in the first direction D1 may be spaced apart from each other by a first distance P1 in the first direction D1. According to some embodiments, the first distance P1 may be 3 um to 30 um. The first distance P1 may be a distance in the first direction D1 between the first side surface S1 of the second conductive line 32 and the first side surface 23a of the third insulating layer 23.

Each of the third conductive lines 33 may have a first width W1 in the first direction D1 and a second width W2 in the second direction D2. According to some embodiments, each of the first width W1 and the second width W2 may be 1 um to 10 um.

Each of the third seed patterns 33p may be interposed between the first side surface 23a of the third insulating layer 23 and each of the third conductive lines 33. Each of the third conductive lines 33 may have a first side surface S1 and a second side surface S2 facing each other in the first direction D1. Each of the third seed patterns 33p may be interposed between the first side surface 23a of the third insulating layer 23 and the second side surface S2 of each of the third conductive lines 33. Each of the third seed patterns 33p may be aligned with the corresponding third conductive line 33 in the first direction D1. Each of the third seed patterns 33p may be horizontally overlapped with the corresponding third conductive line 33.

Each of the third conductive lines 33 may have a length L in the third direction D3. According to some embodiments, the length L may be 7 um to 33 um.

The third seed patterns 33p and the third conductive lines 33 may include substantially the same material as that of the first seed patterns 31p and the first conductive lines 31, respectively.

The fourth insulating layer 24 may be disposed on the first side surface 23a of the third insulating layer 23. The fourth insulating layer 24 may cover the third conductive lines 33. The fourth insulating layer 24 may have a first side surface 24a. The first side surface 24a of the fourth insulating layer 24 may face the first side surface 23a of the third insulating layer 23 in the first direction D1. The fourth conductive line 34 may be disposed on the first side surface 24a of the fourth insulating layer 24. A plurality of fourth conductive lines 34 may be provided. The fourth conductive lines 34 may be spaced apart from each other in the second direction D2 on the first side surface 24a of the fourth insulating layer 24.

The fourth conductive lines 34 adjacent to each other in the second direction D2 may be spaced apart from each other by a second distance P2 in the second direction D2. According to some embodiments, the second distance P2 may be 3 um to 30 um.

The third conductive lines 33 and the fourth conductive lines 34 may be spaced apart from each other in the first direction D1 with a portion of the fourth insulating layer 24 interposed therebetween. Among the third and fourth conductive lines 33 and 34, the third conductive line 33 and the fourth conductive line 34 adjacent to each other in the first direction D1 may be spaced apart from each other by a first distance P1 in the first direction D1. According to some embodiments, the first distance P1 may be 3 um to 30 um. The first distance P1 may be a distance in the first direction D1 between the first side surface S1 of the third conductive line 33 and the first side surface 24a of the fourth insulating layer 24.

Each of the fourth conductive lines 34 may have a first width W1 in the first direction D1 and a second width W2 in the second direction D2. According to some embodiments, each of the first width W1 and the second width W2 may be 1 um to 10 um.

Each of the fourth seed patterns 34p may be interposed between the first side surface 23a of the fourth insulating layer 24 and each of the fourth conductive lines 34. Each of the fourth conductive lines 34 may have a first side surface S1 and a second side surface S2 facing each other in the first direction D1. Each of the fourth seed patterns 34p may be interposed between the first side surface 23a of the fourth insulating layer 24 and the second side surface S2 of each of the fourth conductive lines 34. Each of the fourth seed patterns 34p may be aligned with the corresponding fourth conductive line 34 in the first direction D1. Each of the fourth seed patterns 34p may be horizontally overlapped with the corresponding fourth conductive line 34.

Each of the fourth conductive lines 34 may have a length L in the third direction D3. According to some embodiments, the length L may be 7 um to 33 um.

The fourth seed patterns 34p and the fourth conductive lines 34 may include substantially the same material as that of the first seed patterns 31p and the first conductive lines 31, respectively.

A fifth insulating layer 25 may be disposed on the first side surface 24a of the fourth insulating layer 24. The fifth insulating layer 25 may cover the fourth conductive lines 34.

A connection mold layer 70 may be disposed on the redistribution substrate 200. The connection mold layer 70 may be interposed between the unit chip packages 400 and the redistribution substrate 200, and between the base chip 600 and the redistribution substrate 200. The connection mold layer 70 may extend from an upper surface 200a of the redistribution substrate 200 to the lower chip pads 441 and the base chip pads 641. The connection mold layer 70 may cover the horizontal connection structures 50 and the vertical connection structures 10. The connection mold layer 70 may fill a space between the horizontal connection structures 50 and the vertical connection structures 10. The connection mold layer 70 may include an insulating material (e.g., an epoxy molding compound (EMC)).

A first mold layer MD1 may be disposed on the connection mold layer 70. The first mold layer MD1 may extend from an upper surface of the connection mold layer 70 to the upper surface 600a of the base chip 600. The first mold layer MD1 may cover a side surface of the unit chip package 400 and fill a space between the unit chip package 400 and the base chip 600. The first mold layer MD1 may fill a space between the lower chip pads 441 and the base chip pads 641. The first mold layer MD1 may include an insulating material (e.g., epoxy molding compound (EMC)).

According to the disclosure, the semiconductor package includes the connection structures having relatively small sizes instead of a large-area interposer. That is, by using vertical connection structures 10 and horizontal connection structures 50 having relatively small sizes, warpage that occurs when using a large-area interposer may be prevented. In addition, the interposer substrate may include vertical penetration electrodes for vertical connection, and in this case, there is a limit to reducing a pitch of the vertical penetration electrodes when forming the vertical penetration electrodes. According to the disclosure, when forming the conductive lines 30 of the vertical connection structure 10, it is easy to increase a pitch between the conductive lines 30, and as a result, the pitch limit of the vertical penetration electrodes of the interposer substrate may be overcome. Accordingly, the semiconductor package with improved electrical characteristics and reliability may be provided.

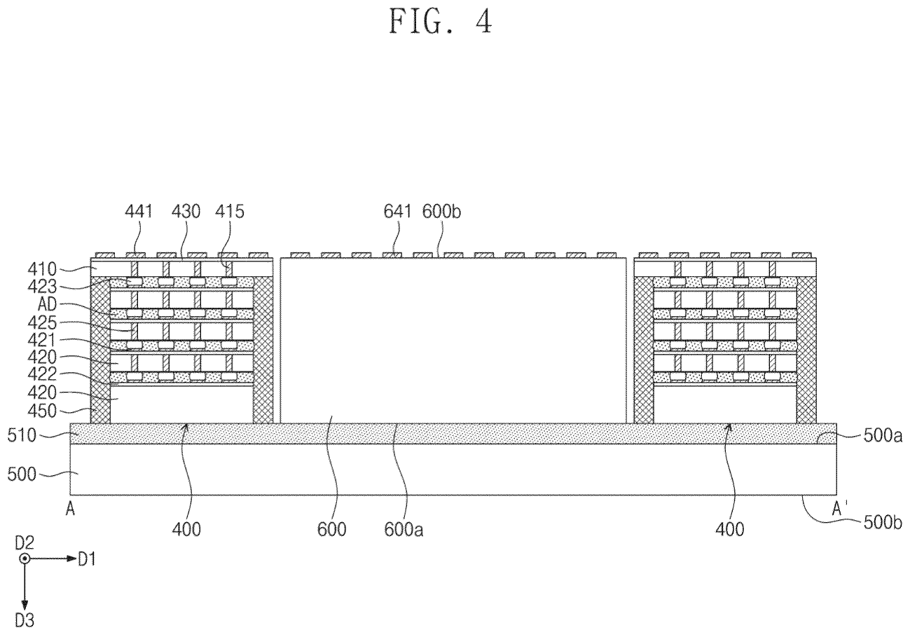

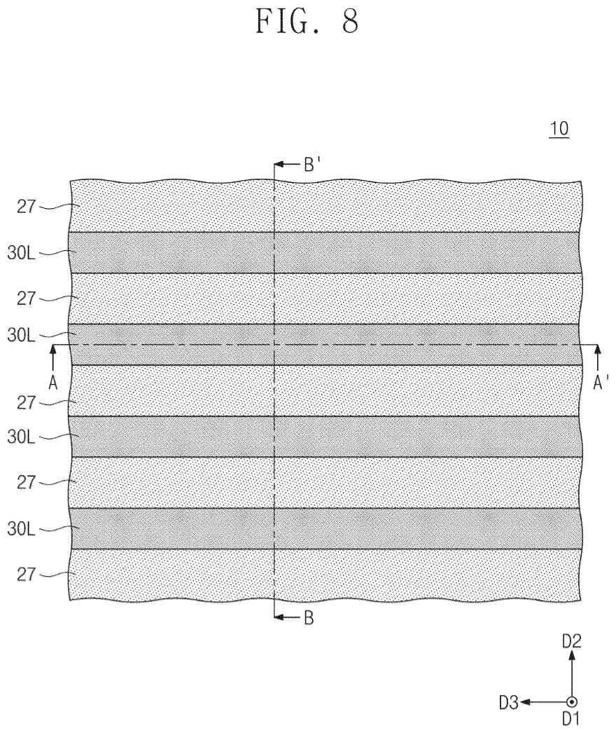

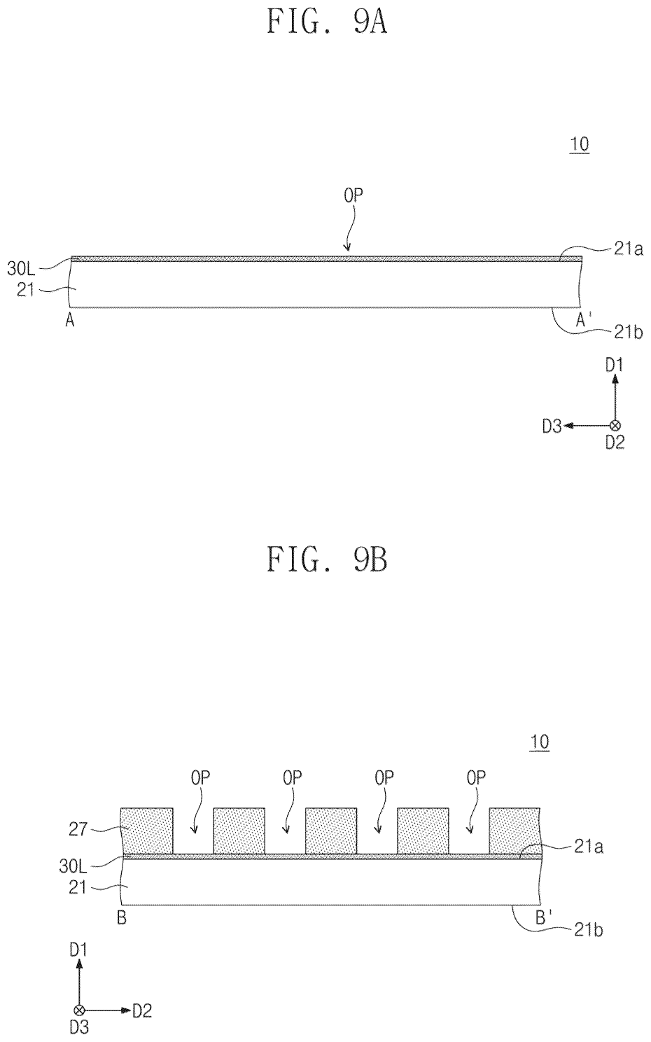

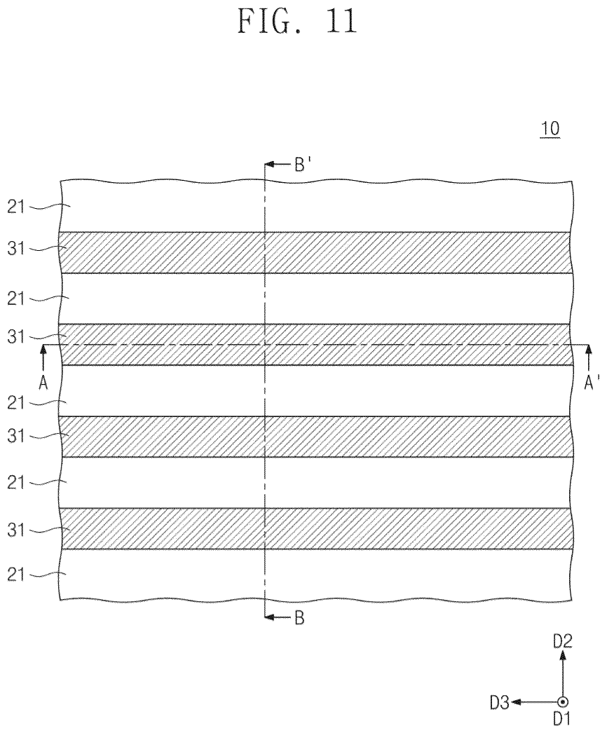

FIGS. 4 to 7, FIG. 15, and FIG. 16 are cross-sectional views illustrating a method of manufacturing a semiconductor package according to some embodiments of the disclosure. FIGS. 8 to 14B are drawings illustrating a method of manufacturing a vertical connection structure according to some embodiments of the disclosure. Specifically, FIGS. 8 and 11 are plan views illustrating a method of manufacturing a vertical connection structure. FIGS. 9A, 10A, 12A, 13A, and 14A are cross-sectional views illustrating a method of manufacturing a vertical connection structure, and are cross-sectional views corresponding to line A-A′ of FIGS. 8 and 11, respectively. FIGS. 9B, 10B, 12B, 13B, and 14B are cross-sectional views illustrating a method of manufacturing a vertical connection structure, and are cross-sectional views corresponding to line B-B′ of FIGS. 8 and 11, respectively. For simplicity of explanation, any description overlapping the semiconductor package described with reference to FIGS. 1, 2, 3A, and 3B will be omitted.

Referring to FIG. 4, a carrier substrate 500 may be provided. The carrier substrate 500 may include an upper surface 500a and a lower surface 500b that face each other in a third direction D3. The third direction D3 may be a direction perpendicular to the upper surface 500a of the carrier substrate 500. A first direction D1 and a second direction D2 may be directions that are parallel to the upper surface 500a of the carrier substrate 500 and intersect each other. For example, the first to third directions D1, D2, and D3 may be directions that are orthogonal to each other.

An adhesive layer 510 may be formed on the upper surface 500a of the carrier substrate 500. Unit chip packages 400 and base chips 600 may be provided on the adhesive layer. The unit chip packages 400 and base chips 600 may be substantially the same as those described above with reference to FIGS. 1 and 2, respectively. The unit chip packages 400 and the base chip 600 may be horizontally spaced apart from each other. The unit chip packages 400 may be spaced apart from each other in the first direction D1 with the base chip 600 interposed therebetween. The base chip 600 may be disposed in a form in which an upper surface 600a is adjacent to the adhesive layer 510. Each of the unit chip packages 400 may be disposed in a form in which the upper surface of the uppermost semiconductor chip 420 among the plurality of semiconductor chips 420 is adjacent to the adhesive layer 510. That is, the base chip 600 and the unit chip packages 400 may be attached on the adhesive layer 510 in an upside-down form.

Each of the unit chip packages 400 may include lower chip pads 441 on the lower circuit layer 430 of a lower semiconductor chip 410. The base chip 600 may include base chip pads 641 on the lower surface 600b.

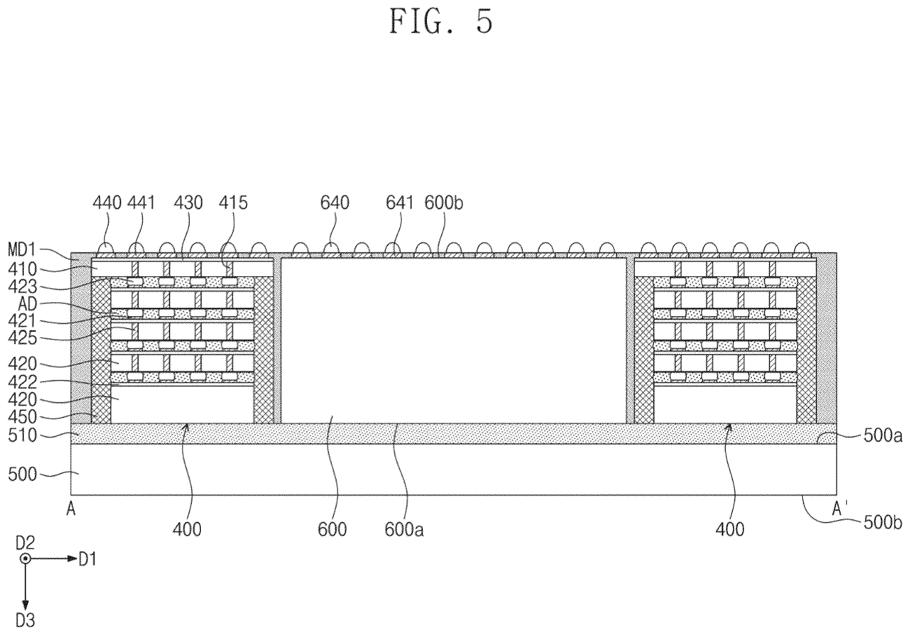

Referring to FIG. 5, a first mold layer MD1 may be formed on the entire surface of a semiconductor package being manufactured. The first mold layer MD1 may extend from the adhesive layer 510 to the lower chip pads 441 and the base chip pads 641. The first mold layer MD1 may fill a space between the unit chip packages 400 and the base chip 600. The first mold layer MD1 may expose the lower chip pads 441 and the base chip pads 641.

Subsequently, lower connection terminals 440 and base connection terminals 640 may be formed. The lower connection terminals 440 may be formed on the lower chip pads 441, respectively, and the base connection terminals 640 may be formed on the base chip pads 641, respectively.

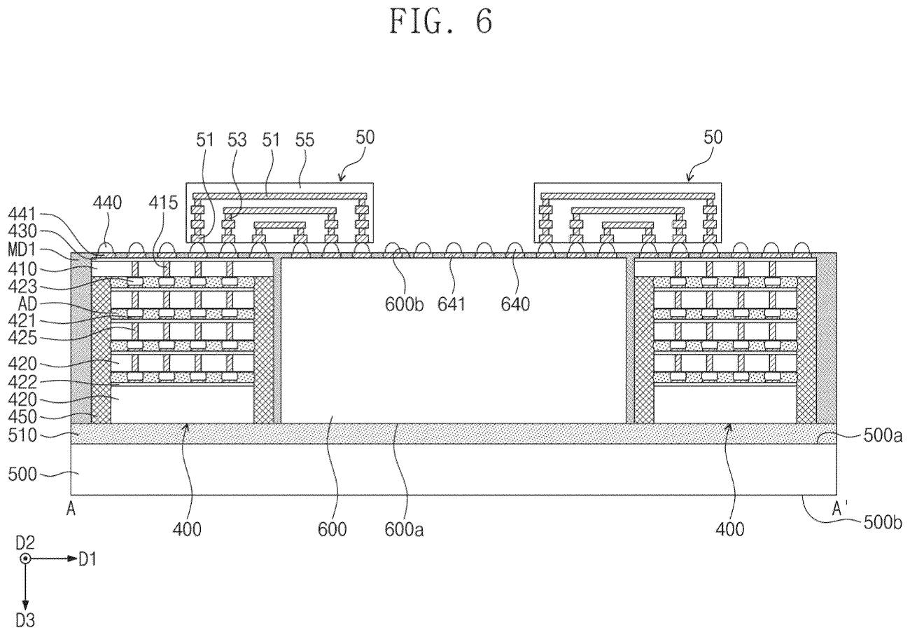

Referring to FIG. 6, horizontal connection structures 50 may be formed on the unit chip package 400 and the base chip 600. The horizontal connection structures 50 may be formed in an appropriate size depending on a design and may be assembled to connect the unit chip package 400 and the base chip 600. Each of the horizontal connection structures 50 may be disposed between the adjacent unit chip package 400 and the base chip 600.

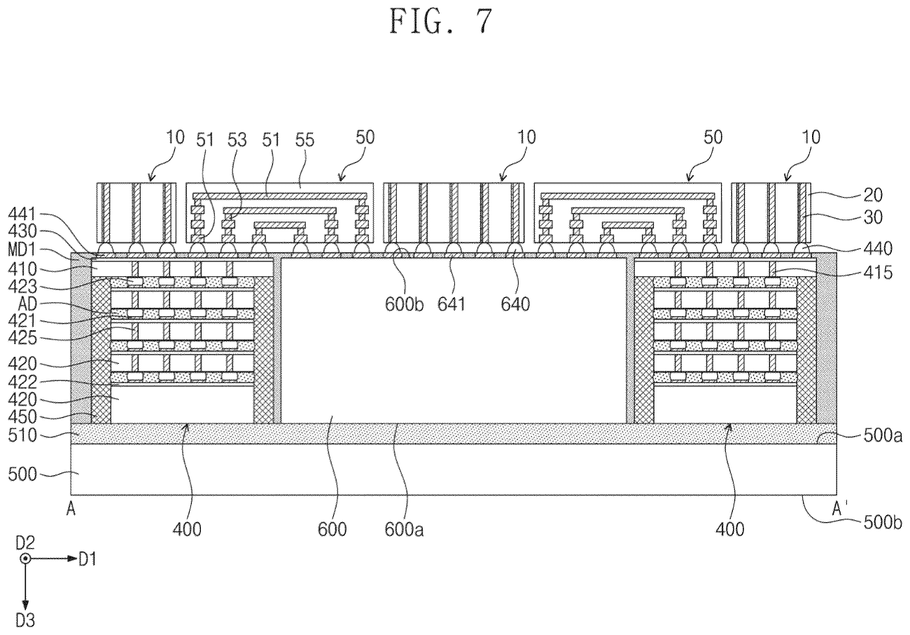

Referring to FIG. 7, vertical connection structures 10 may be formed on the unit chip package 400 and the base chip 600. The vertical connection structures 10 may be spaced apart from the horizontal connection structures 50 in a horizontal direction. The vertical connection structures 10 may be formed in an appropriate size depending on a design and may be assembled on the unit chip package 400 and the base chip 600. The conductive lines 30 of the vertical connection structures 10 may be assembled so that the conductive lines 30 are connected to the lower connection terminals 440 and the base connection terminals 640. The formation of the vertical connection structures 10 is described below.

Referring to FIGS. 8, 9A, and 9B, a seed layer 30L may be formed on an upper surface 21a of the first insulating layer 21. The first insulating layer 21 may have an upper surface 21a and a lower surface 21b that face each other in the first direction D1. The seed layer 30L may include, for example, at least one of copper, titanium, tungsten, and nickel.

A mask pattern 27 may be formed on the seed layer 30L. The mask pattern 27 may include a plurality of openings OP. Each of the openings OP may extend in the third direction D3. The openings OP may be spaced apart from each other in the second direction D2. The mask pattern 27 may be formed, for example, through a coating, exposure, and development process of a photoresist layer. A portion of an upper surface of the seed layer 30L may be exposed through the openings OP.

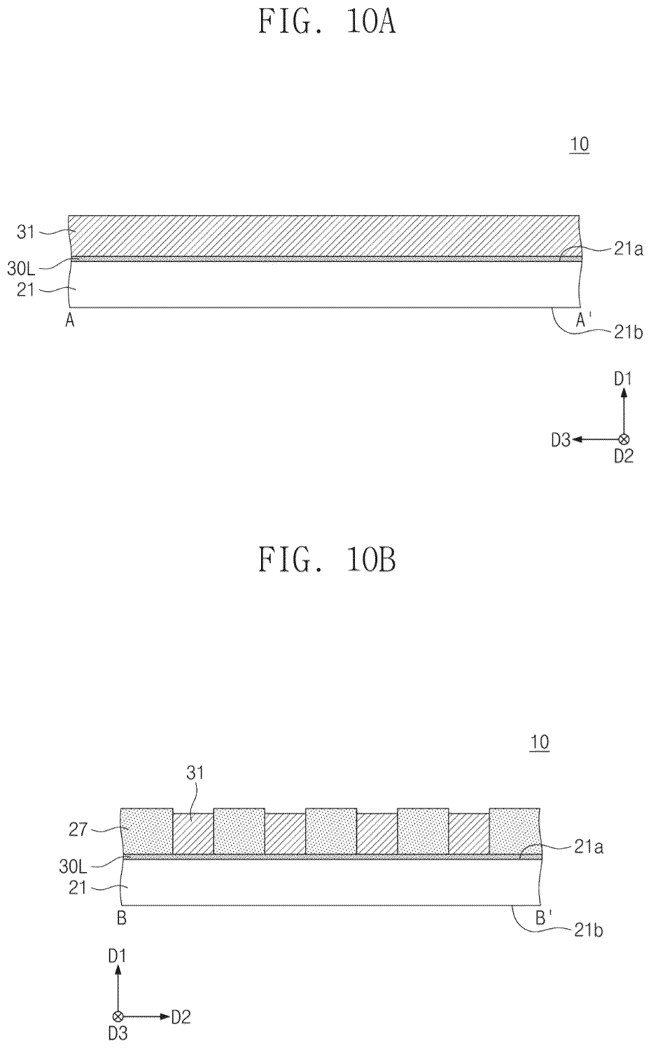

Referring to FIGS. 10A and 10B, first conductive lines 31 may be formed in the openings OP of the mask pattern 27. Forming the first conductive lines 31 may be performed, for example, through an electroplating process using the seed layer 30L as an electrode. Each of the first conductive lines 31 may extend in the third direction D3. The first conductive lines 31 may be spaced apart from each other in the second direction D2. An upper surface of the first conductive lines 31 in the first direction D1 may be disposed at a lower height than that of the mask pattern 27.

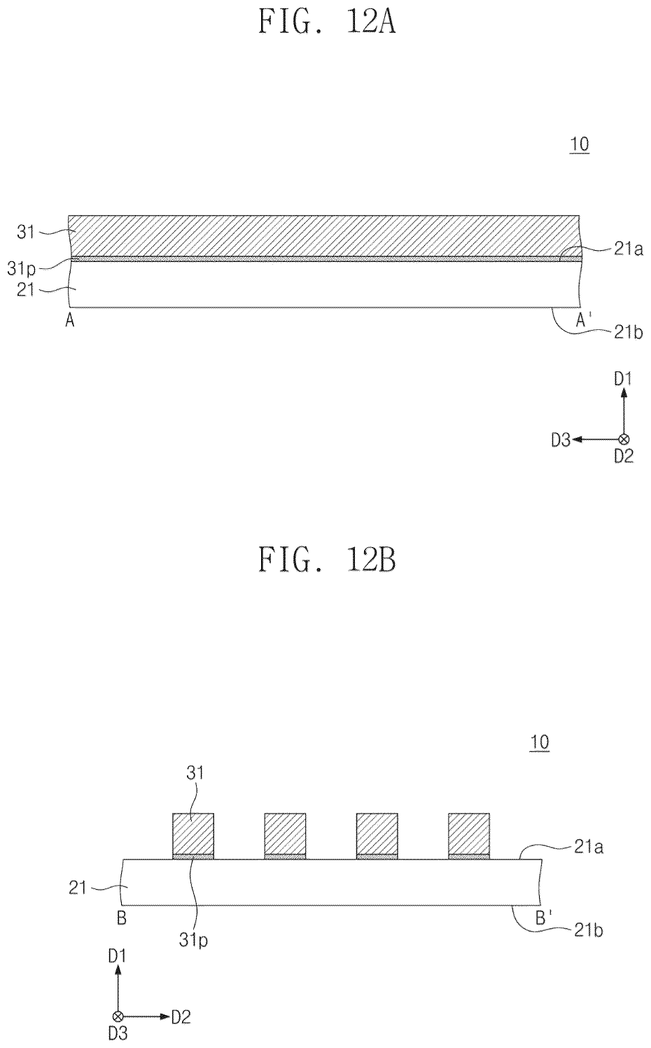

Referring to FIGS. 11, 12A, and 12B, the mask pattern 27 may be removed. Removing the mask pattern 27 may include, for example, an ashing process and a strip process.

Subsequently, the first seed patterns 31p may be formed. Forming the first seed patterns 31p may include, for example, etching the seed layer 30L using the first conductive lines 31 as an etching mask.

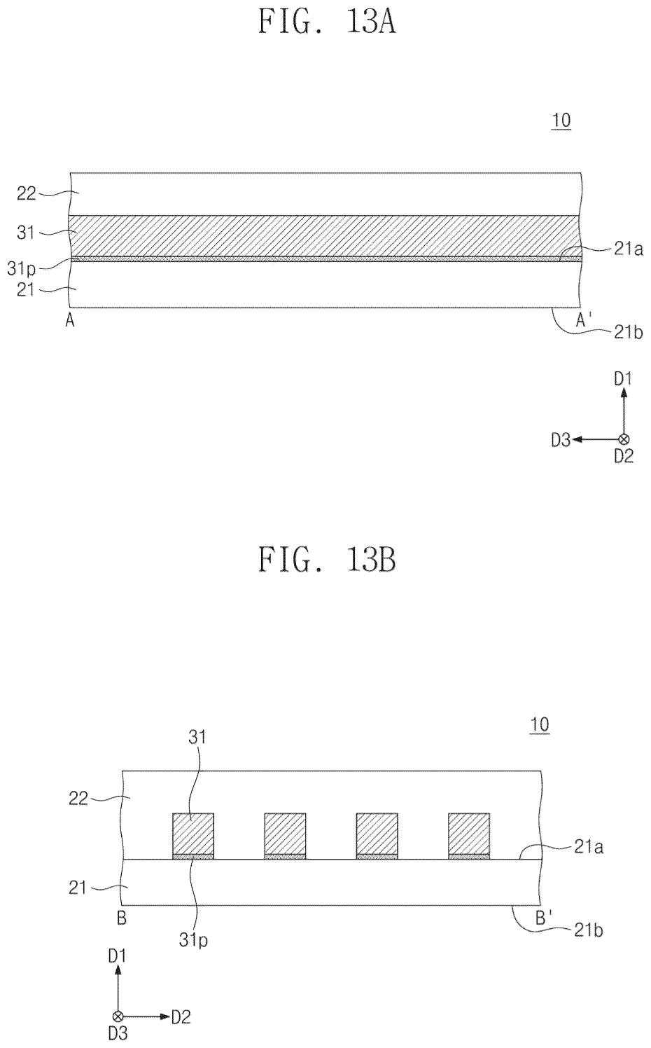

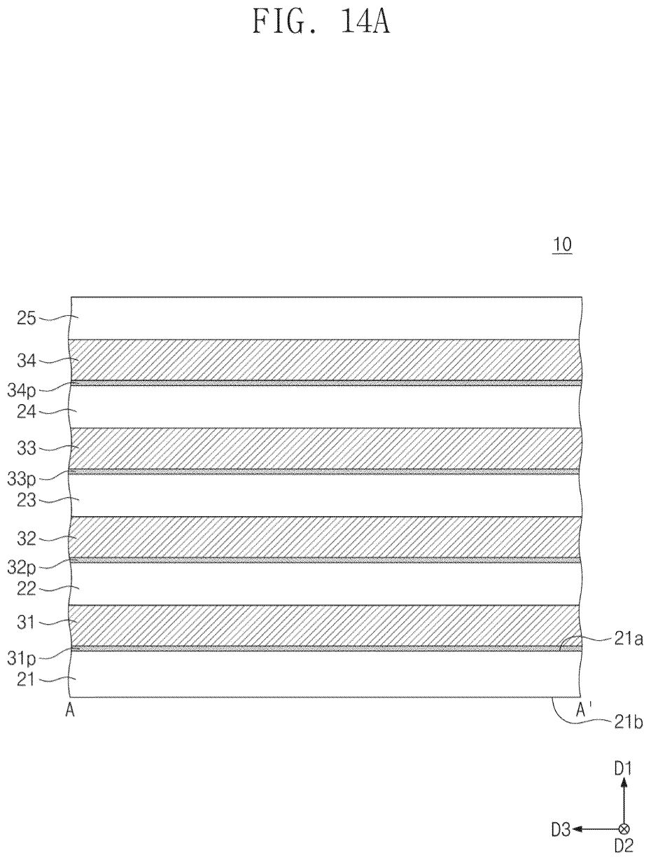

Referring to FIGS. 13A and 13B, a second insulating layer 22 may be formed on the upper surface 21a of the first insulating layer 21. The second insulating layer 22 may be formed to cover the first conductive lines 31.

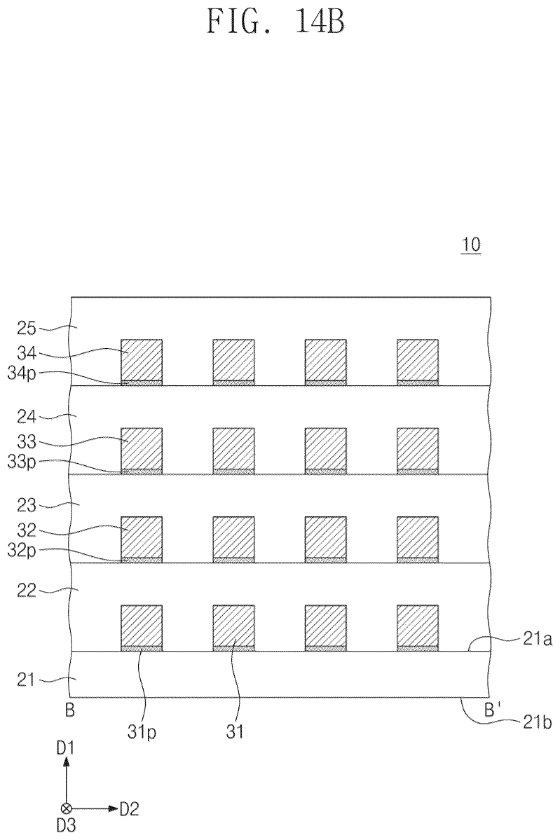

Referring to FIGS. 14A and 14B, second to fourth seed patterns 32p, 33p, and 34p, the second to fourth conductive lines 32, 33, and 34, and the third to fifth insulating layers 23, 24, and 25 may be formed on the second insulating layer 22. This may be formed by repeatedly performing substantially the same method as described above with reference to FIGS. 8 to 13B.

Forming the conductive lines 30 is not limited to the above-described method. As another example, a method including forming a conductive line layer on a seed layer and forming a mask pattern to pattern the conductive line layer may also be used.

According to the disclosure, as the conductive lines 30 are formed by the above-described method, process difficulty may be reduced and cost may be reduced compared to forming the vertical penetration electrode of the conventional interposer substrate. In addition, a pitch between the conductive lines 30 may be easily increased.

Referring to FIG. 7 again, the vertical connection structure 10 manufactured by the above-described process may be rotated 90 degrees. For example, the vertical connection structure 10 of FIG. 14A and FIG. 14B may be rotated 90 degrees to the right and may be assembled on the unit chip package 400 and the base chip 600. The vertical connection structure 10 may be provided in various sizes and may be assembled depending on a design. Accordingly, the upper surfaces 21a to 25a of the first to fifth insulating layers 21 to 25 may correspond to the first side surfaces 21a to 25a of the first to fifth insulating layers 21 to 25 described above with reference to FIGS. 3A and 3B. Similarly, the lower surfaces 21b to 25b of the first to fifth insulating layers 21 to 25 may correspond to the second side surfaces 21b to 25b of the first to fifth insulating layers 21 to 25 described above with reference to FIGS. 3A and 3B.

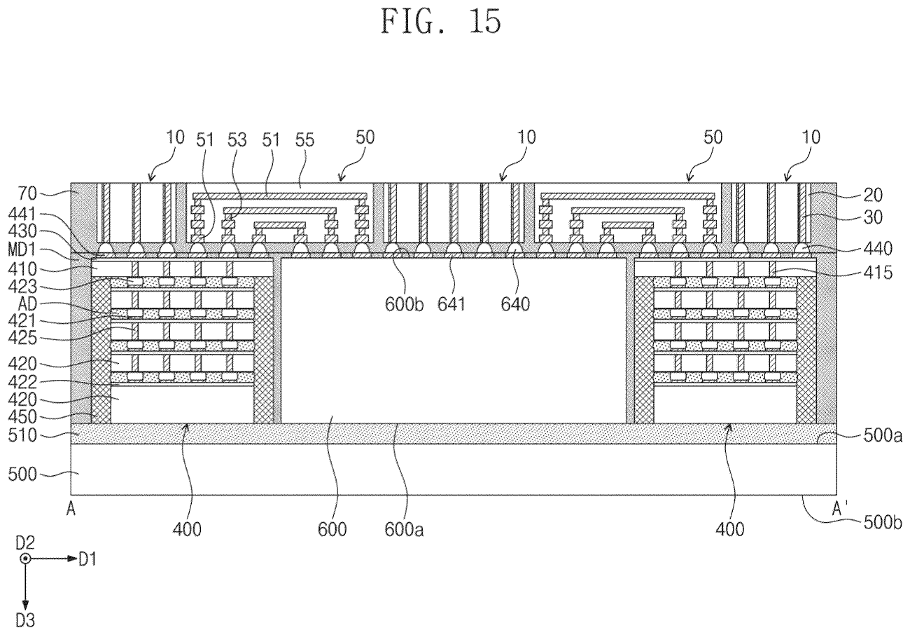

Referring to FIG. 15, a connection mold layer 70 may be formed on the first mold layer MD1. The connection mold layer 70 may fill a space between the vertical connection structures 10 and the horizontal connection structures 50. The connection mold layer 70 may fill a space between the lower connection terminals 440 and the base connection terminals 640.

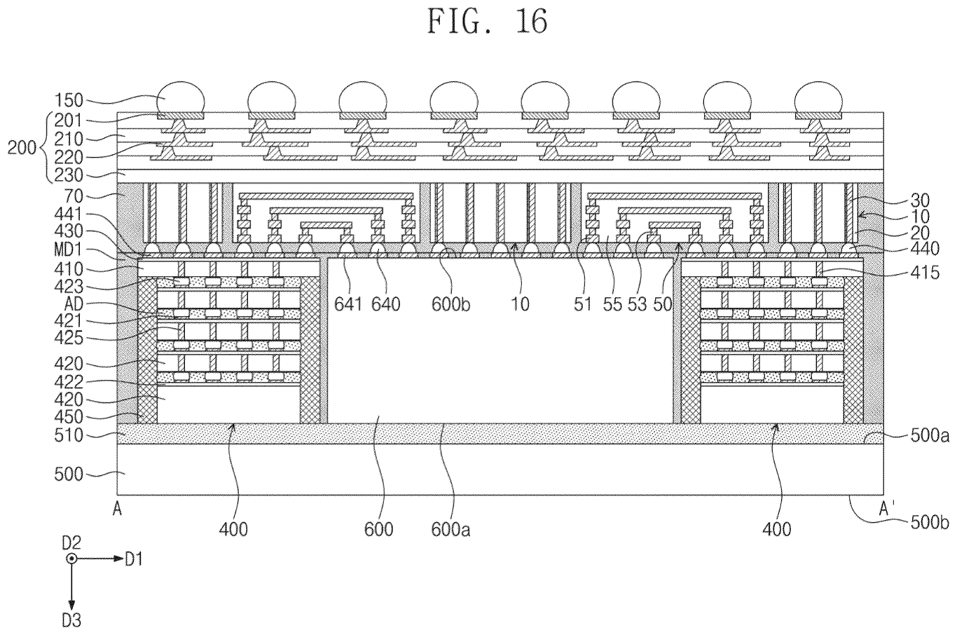

Referring to FIG. 16, a redistribution substrate 200 may be formed. Subsequently, external redistribution connection terminals 150 may be formed on the redistribution substrate 200.

Referring again to FIG. 2, the carrier substrate 500 and the adhesive layer 510 may be removed. Thereafter, when the semiconductor package being manufactured is turned over, the semiconductor package of FIG. 2 may be completed.

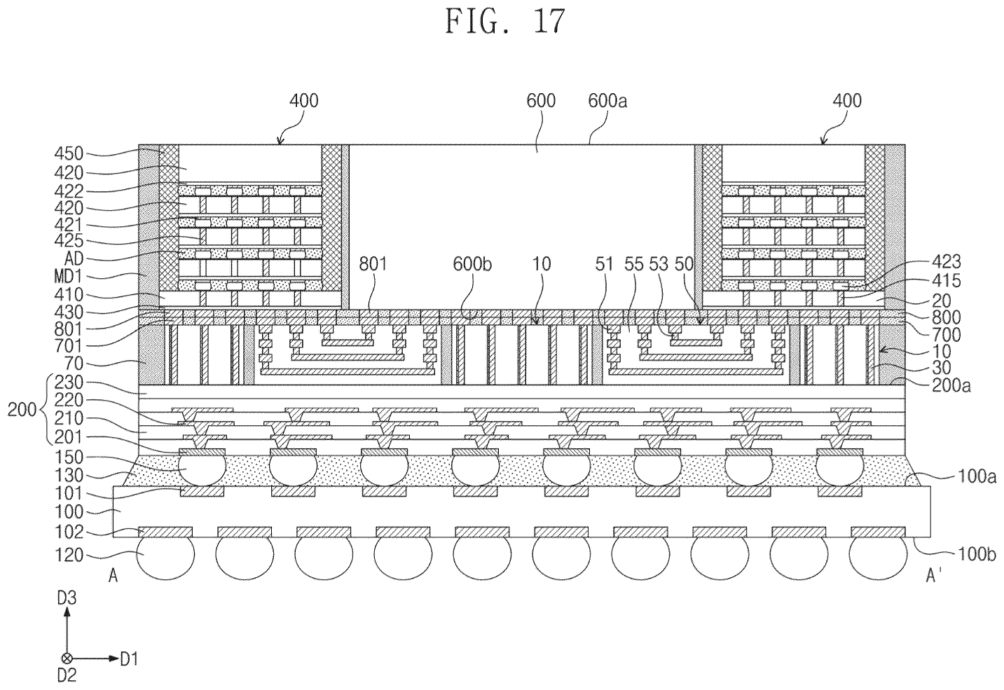

FIG. 17 is a cross-sectional view illustrating a semiconductor package according to some embodiments of the disclosure, and is a cross-sectional view along A-A′ of FIG. 1. For simplicity of explanation, any content that overlaps what has been described above is omitted.

Referring to FIG. 1 and FIG. 17, a first protective layer 700 may be disposed on the connection mold layer 70. The first protective layer 700 may be disposed on the vertical connection structure 10 and the horizontal connection structure 50. A second protective layer 800 may be disposed on a lower surface of the first mold layer MD1. The second protective layer 800 may be disposed on the lower surface 600b of the base chip 600. The second protective layer 800 may extend onto the lower circuit layer 430 of the unit chip package 400. The first and second protective layers 700 and 800 may be interposed between the base chip 600 and the vertical connection structure 10, and the horizontal connection structure 50, and may extend between the unit chip package 400 and the vertical connection structure 10, and the horizontal connection structure 50. The first and second protective layers 700 and 800 may include at least one of silicon oxide (SiO₂), silicon nitride (SiN), silicon carbonitride (SiCN), and silicon carboxyde (SiCO).

The unit chip package 400 and the base chip 600, and the vertical connection structures 10 and the horizontal connection structures 50 may be combined by hybrid bonding between the first protective layer 700 and the second protective layer 800 and may come into contact with each other. In this specification, hybrid bonding means bonding in which two components including the same material are fused at their interface.

A first bonding pad 701 may be disposed in the first protective layer 700. A plurality of first bonding pads 701 may be provided. The first bonding pads 701 may be spaced apart from each other in the first direction D1 and/or the second direction D2. The first bonding pads 701 may be respectively connected to the horizontal circuit wiring lines 51 of the horizontal connection structure 50. The first bonding pads 701 may be respectively connected to the conductive lines 30 of the vertical connection structure 10.

A second bonding pad 801 may be disposed in the second protective layer 800. A plurality of second bonding pads 801 may be provided. The second bonding pads 801 may be spaced apart from each other in the first direction D1 and/or the second direction D2.

The first bonding pads 701 may be in contact with the second bonding pads 801, respectively. That is, the first bonding pads 701 may be in contact with the corresponding second bonding pads 801, respectively. The first protective layer 700 and the second protective layer 800 may be bonded through hybrid bonding. In addition, a metal-to-metal hybrid bonding process by surface activation may be performed at an interface between the first bonding pads 701 included in the first protective layer 700 and the second bonding pads 801 included in the second protective layer 800.

The semiconductor package according to the disclosure the relatively small-sized vertical connection structures and horizontal connection structures may be used instead of the large-area interposer substrate, thereby preventing the warpage that occurs when using the large-area interposer.

In addition, the conductive lines of the vertical connection structure may overcome the pitch limit of the vertical penetration electrode. Accordingly, the difficulty of the manufacturing process may be reduced, and the semiconductor package with the improved electrical characteristics and reliability may be provided.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the spirit and scope of the inventive concept being indicated by the appended claims.

What is claimed is:

1. A semiconductor package comprising:
a substrate;
a unit chip package on the substrate;
a base chip horizontally spaced apart from the unit chip package on the substrate;
a first vertical connection structure between the substrate and the unit chip package; and
a second vertical connection structure between the substrate and the base chip,
wherein one of the first vertical connection structure and the second vertical connection structure comprises:
conductive lines spaced apart in a first direction and a second direction that are parallel to an upper surface of the substrate and intersect, wherein the conductive lines each have a first side surface and a second side surface that faces the first side surface in the first direction; and
a seed pattern in contact with the conductive lines,
wherein the seed pattern is in contact with second side surfaces of the conductive lines.

2. The semiconductor package of claim 1, wherein a first distance in the first direction between adjacent ones of the conductive lines in the first direction is 3 um to 30 um.

3. The semiconductor package of claim 1, wherein the conductive lines have a rectangular shape when viewed in a plan view.

4. The semiconductor package of claim 1, wherein the conductive lines have a rectangular pillar shape extending in a third direction perpendicular to the upper surface of the substrate.

5. The semiconductor package of claim 1, wherein a second distance between adjacent ones of the conductive lines in the second direction is 3 to 30 um.

6. The semiconductor package of claim 1, wherein first widths of the conductive lines in the first direction are 1 to 10 um.

7. The semiconductor package of claim 1, wherein second widths of the conductive lines in the second direction are 1 to 10 um.

8. The semiconductor package of claim 1, further comprising:
a horizontal connection structure connecting the unit chip package and the base chip, between the unit chip package and the substrate, and extending between the base chip and the substrate.

9. The semiconductor package of claim 8, wherein the horizontal connection structure is horizontally spaced apart from the first vertical connection structure and the second vertical connection structure.

10. The semiconductor package of claim 8, wherein the unit chip package is connected to the substrate through the first vertical connection structure and the base chip is connected to the substrate through the second vertical connection structure.

11. The semiconductor package of claim 1, wherein the conductive lines have lengths of 7 um to 33 um in a third direction perpendicular to the upper surface of the substrate.

12. A semiconductor package comprising:
a substrate;
a unit chip package on the substrate;
a base chip horizontally spaced apart from the unit chip package on the substrate;
a first vertical connection structure between the substrate and the unit chip package; and
a second vertical connection structure between the substrate and the base chip,
wherein one of the first vertical connection structure and the second vertical connection structure comprises conductive lines, and
wherein the conductive lines have a rectangular shape when viewed in a plan view and have a rectangular pillar shape extending in a vertical direction perpendicular to an upper surface of the substrate.

13. The semiconductor package of claim 12,
wherein the conductive lines are spaced apart in a first direction and a second direction that are parallel to the upper surface of the substrate and intersect, and
wherein a first distance in the first direction between adjacent ones of the conductive lines in the first direction is 3 um to 30 um.

14. The semiconductor package of claim 12,
wherein the conductive lines are spaced apart in a first direction and a second direction that are parallel to the upper surface of the substrate and intersect, and
wherein a second distance of adjacent ones of the conductive lines in the second direction is 3 um to 30 um.

15. The semiconductor package of claim 12, further comprising:
a seed pattern in contact with the conductive lines,
wherein the conductive lines each have a first side surface and a second side surface that faces the first side surface in a first direction parallel to the upper surface of the substrate, and
wherein the seed pattern is in contact with second side surfaces of the conductive lines.

16. The semiconductor package of claim 12,
wherein the conductive lines have a first widths of 1 um to 10 um in a first direction parallel to the upper surface of the substrate, and
wherein the conductive lines have a second widths of 1 um to 10 um in a second direction parallel to the upper surface of the substrate and intersecting the first direction.

17. A semiconductor package comprising:
a package substrate;
a substrate on the package substrate;
a unit chip package on the substrate;
a base chip on the substrate and spaced apart from the unit chip package in a first direction parallel to an upper surface of the package substrate;
a horizontal connection structure between the unit chip package and the substrate and extending from the base chip to the substrate;
a first vertical connection structure between the substrate and the unit chip package; and
a second vertical connection structure between the substrate and the base chip,
wherein the horizontal connection structure connects the unit chip package and the base chip through lower connection terminals of the unit chip package and base connection terminals of the base chip,
wherein one of the first vertical connection structure and the second vertical connection structure comprises:
conductive lines spaced apart in the first direction and a second direction parallel to the upper surface of the package substrate and intersecting the first direction; and
a seed pattern in contact with the conductive lines,
wherein the conductive lines each have a first side surface and a second side surface facing the first side surface in the first direction, and
wherein the seed pattern is in contact with second side surfaces of the conductive lines.

18. The semiconductor package of claim 17, wherein the conductive lines have a rectangular shape when viewed in a plan view and has a square pillar shape extending in a third direction perpendicular to the upper surface of the package substrate.

19. The semiconductor package of claim 17, wherein a first distance between the conductive lines adjacent in the first direction is 3 um to 30 um, and
wherein a second distance between adjacent ones of the conductive lines in the second direction is 3 um to 30 um.

20. The semiconductor package of claim 17, further comprising:
connection terminals between the package substrate and the substrate; and
an underfill pattern on side surfaces of the connection terminals.
